(19) United States
(12) Patent Application Publication
(10) Pub. No.: US 2009/0236689 A1
(43) Pub. Date: Sep. 24, 2009

(54) INTEGRATED PASSIVE DEVICE AND METHOD WITH LOW COST SUBSTRATE

(75) Inventors: Terry K. Daly, Gilbert, AZ (US); Keri L. Costello, Chandler, AZ (US); James G. Cotronakis, Chandler, AZ (US); Jason R. Fender, Chandler, AZ (US); Jeff S. Hughes, Mesa, AZ (US); Agni Mitra, Gilbert, AZ (US); Adolfo C. Reyes, Tempe, AZ (US)

Correspondence Address: INGRASSIA FISHER & LORENZ, P.C. (FS), 7010 E. COCHISE ROAD, SCOTTSDALE, AZ, 85253, US

(73) Assignee: FREESCALE SEMICONDUCTOR, INC., Austin, TX (US)

(21) Appl. No.: 12/054,105

(22) Filed: Mar. 24, 2008

(51) Int. Cl. H01L 29/00; H01L 21/20

(52) U.S. Cl. 257/531; 438/382; 438/393; 257/532; 257/536; 257/E29.218; 257/E21.09

(57) ABSTRACT

According to one aspect of the present invention, a method of forming a microelectronic assembly, such as an integrated passive device (72), is provided. An insulating initial dielectric layer (32) comprising charge trapping films of, for example, aluminum nitride or silicon nitride or silicon oxide or a combination thereof, is formed over a silicon substrate (20). At least one passive electronic component (62) is formed over the initial dielectric layer (32). In an embodiment where silicon nitride or oxide is used in the initial dielectric layer (32) in contact with the silicon substrate (20), it is desirable to pre-treat the silicon surface (22) by exposing it to a surface damage causing treatment (e.g. an argon plasma) prior to depositing the initial dielectric layer, to assist in providing carrier depletion near the silicon surface around zero bias. RF loss in integrated passive devices using such silicon substrates is equal or lower than that obtained with GaAs substrates.

### FIELD OF THE INVENTION

The present invention generally relates to microelectronic assemblies and a method for forming microelectronic assemblies, and more particularly relates to integrated passive devices (IPDs) with low cost substrates and a method for forming such IPDs.

### BACKGROUND OF THE INVENTION

In recent years, wireless communication devices, such as cellular phones, have continued to offer an ever increasing amount of features to users, along with improved performance and computing power, while the overall size of the devices has continued to decrease. One important type of components found in such devices is referred to as “passive electronic components,” including capacitors, resistors, transmission lines and inductors. Often, these components work together to perform various electronic functions such as harmonic filtering, decoupling, impedance matching, and switching.

In years past, discrete passive electronic components were used in wireless communication devices and mounted to various circuit boards and substrates. However, as performance demands continue to increase while the overall size of the finished devices decreases, it is becoming increasingly difficult to fit all of the desired components into the finished wireless device.

In recent years, integrated passive devices (IPDs) have been developed, in which the passive electronic components are formed directly onto substrates (e.g., wafers or microelectronic die), sometimes in conjunction with active electronic components, such as transistors. However, in order to optimize performance, IPDs are typically formed on relatively high resistivity substrates, such as those made of gallium arsenide (GaAs), glass, quartz, or sapphire, as opposed to silicon, which is generally considered to have too low a resistivity to be used in IPDs for wireless communication devices.

One problem associated with forming IPDs on such high resistivity substrates is that these materials are considerably more expensive than silicon. Additionally, the manufacturing tools and processes used to form integrated circuits, for example and not intended to be limiting, complementary metal-oxide semiconductor (CMOS) processing on silicon substrates, must be modified in order to use, glass, quartz, or sapphire substrates. These process modifications further increase manufacturing costs, as well as production time.

Accordingly, it is desirable to provide a structure and method for manufacturing IPDs on less expensive substrates, such as silicon, without sacrifice of important performance characteristics. Additionally, it is desirable to provide a method for manufacturing IPDs that utilizes the same processing tools and similar process steps used to form integrated circuits with active electronic components. Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

The present invention will hereinafter be described in conjunction with the following drawings, wherein like numerals denote like elements, and

FIG. 1 is a top plan view of a semiconductor substrate;

FIG. 2 is a cross-sectional side view of a portion of the semiconductor substrate of FIG. 1;

FIG. 3 is a cross-sectional side view of the semiconductor substrate of FIGS. 1 and 2 with an initial dielectric layer formed thereon;

FIG. 4 is a cross-sectional side view of the semiconductor substrate of FIG. 3 with an adhesion layer formed over the initial dielectric layer;

FIG. 5 is a cross-sectional side view of the semiconductor substrate of FIG. 4 with a first conductive layer formed over the adhesion layer;

FIG. 6 is a cross-sectional side view of the semiconductor substrate of FIG. 5 after the first conductive layer has been patterned to form a first conductive plate;

FIG. 7 is a cross-sectional side view of the semiconductor substrate of FIG. 6 with a further dielectric layer formed over the first conductive plate;

FIG. 8 is a cross-sectional side view of the semiconductor substrate of FIG. 7 with a second conductive layer formed over the further dielectric layer;

FIG. 9 is a cross-sectional side view of the semiconductor substrate of FIG. 8 after the second conductive layer and the further dielectric layer have been patterned to form a second conductive plate with a dielectric body between the first and second conductive plates;

FIG. 10 is an expanded cross-sectional side view of the semiconductor substrate of FIG. 9 after the formation of multiple passive electronic components thereon, thus forming a microelectronic assembly according to one embodiment of the present invention;

FIG. 11 is a schematic view of a power amplifier (PA) module in which the microelectronic assembly of FIG. 10 may be utilized;

FIGS. 12-17 are views analogous to that of FIG. 5, but showing the use of different initial dielectric layers and surface treatments according to various embodiments of the present invention;

FIG. 18 is a table and chart showing signal attenuation for different substrates, substrate surface treatments and initial dielectric layers, according to various embodiments of the invention; and

FIG. 19 is a table and chart analogous to that of FIG. 18 showing further details of signal attenuation for a sub-set of the substrates, substrate surface treatments and initial dielectric layers illustrated in FIG. 18; and

FIG. 20 is a chart showing signal attenuation as a function of the number of thermal cycles to which an IPD structure has been subjected, for various types of substrates and initial dielectric layers.

### DETAILED DESCRIPTION OF THE INVENTION

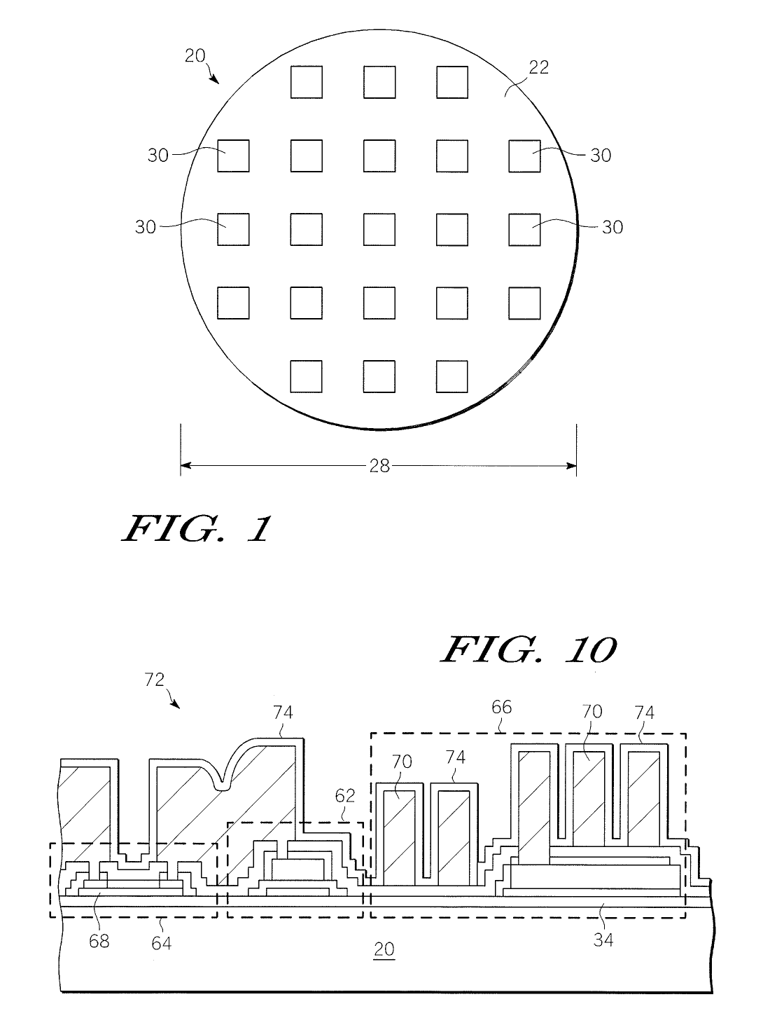

The following detailed description is merely exemplary in nature and is not intended to limit the invention or application and uses of the invention. Furthermore, there is no intention to be bound by any expressed or implied theory presented in the preceding technical field, background, brief summary, or the following detailed description. It should also be noted that FIGS. 1-20 are merely illustrative and may not be drawn to scale.

FIG. 1 to FIG. 10 illustrate a method for forming an integrated passive device (IPD). An initial dielectric layer is formed on a silicon substrate, preferably a high resistivity (HR) silicon substrate, and at least one passive electronic component is formed over the initial dielectric layer. A combination of the choice of material for the initial dielectric layer, deposition process for the initial dielectric layer and pre-treatment of the silicon surface prior to deposition of the initial dielectric layer, can increase the effective resistivity of the silicon substrate so that the silicon substrate is suitable for use in IPDs used in, for example, wireless communications devices, as well as other radio frequency (RF) devices, and is comparable in performance to much more expensive substrate materials such as, for example, GaAs.

Referring to FIGS. 1 and 2, there is illustrated semiconductor substrate 20. Semiconductor substrate 20 is made of a semiconductor material, such as silicon (Si). In a preferred embodiment, substrate 20 is a silicon substrate with a resistivity of at least 1000 ohm-centimeters (cm), which may be referred to as a “high resistivity” substrate, abbreviated as “HR” in the context of silicon. As will be appreciated by one skilled in the art, the resistivity of the substrate 20 may be increased by purifying the silicon, such as by applying a magnetic field to the silicon during the formation of the ingot from which the substrate is cut. The substrate ingot may be grown by well known techniques, such as “floatzone”, or liquid encapsulated Czochraski (LEC) techniques.

Still referring to FIGS. 1 and 2, substrate 20 has an upper surface 22, lower surface 24, and thickness 26 of, for example, between approximately 25 and 800 micrometers (μm), preferably between 25 and 625 μm. In one embodiment, upper surface 22 of substrate 20 is substantially planar and the thickness 26 of the substrate 20 is approximately 250 μm. In the depicted embodiment, substrate 20 is a semiconductor wafer with diameter 28 of, for example, approximately 100, 150, 200, or 300 millimeters (mm), but larger or smaller substrates can also be used. In general, thickness 26 is increased as diameter 28 is increased so that the wafers can be handled without undue breakage. As illustrated specifically in FIG. 1, substrate 20 may be divided into multiple die or “dice” 30 containing integrated passive devices (IPDs). Although not shown, in one embodiment, each of dice 30 may include an at least partially formed integrated circuit, such as a microprocessor or a power integrated circuit, as is commonly understood, which may include numerous devices, such as transistors, formed therein. Although the following process steps may be shown as being performed on only a small portion of the substrate 20, it should be understood that each of the steps may be performed on substantially the entire substrate 20 and/or multiple dice 30, simultaneously. Furthermore, although not shown, it should be understood that the processing steps described below may be facilitated by the deposition and removal of multiple additional processing layers, such as photoresist, as is commonly understood.

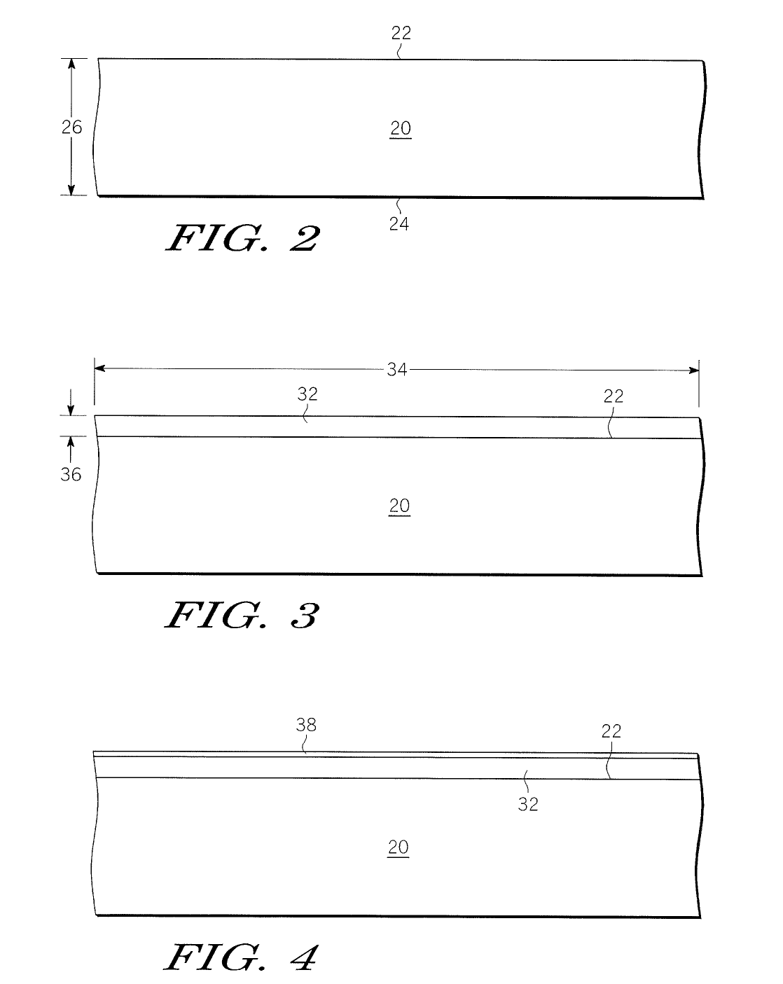

Referring to FIG. 3, insulating initial dielectric layer 32 is formed on (or over) upper surface 22 of the substrate 20. In one embodiment, initial dielectric layer 32 includes a nitride material, such a silicon nitride formed using chemical vapor deposition (CVD) or by other well known techniques. In another embodiment, initial dielectric layer 32 includes another nitride material, such as aluminum nitride formed using sputtering or other well known techniques. In still further embodiments, the initial dielectric layer may also include an oxide dielectric material such as silicon oxide formed by chemical vapor deposition (CVD) or plasma enhanced chemical vapor deposition (PECVD) or other well known techniques, in combination with one or the other of the above-mentioned nitride materials. In still further embodiments, surface 22 of substrate 20 may be pre-treated, e.g., etched or subjected to other surface damaging treatment, prior to deposition of one or the other of the above-mentioned initial dielectric materials. In preferred embodiments, insulating initial dielectric layer 32 comprises sputtered aluminum nitride alone or in combination with CVD silicon nitride, with or without a pre-deposition etch of the substrate surface or other surface damaging treatment. Silicon oxide may also be used in combination with the aluminum or silicon nitride. Surface pre-treatment is conveniently performed by exposing surface 22 of wafer substrate 20 to an RF argon plasma for 0.5-3.5 minutes, more conveniently for about 1 to 3 minutes, and preferably for about 2.2 minutes. Aluminum nitride is preferably formed by DC sputtering of an aluminum target in flowing nitrogen gas. However, other deposition techniques may also be used. Silicon nitride is preferably formed by plasma enhanced chemical vapor deposition (PE-CVD) using silane (SiH₄) and, when included, silicon oxide (e.g., SiO₂) is preferably formed using plasma enhanced CVD (PECVD) in which tetraethyl orthosilicate or tetraethoxysilane (TEOS) is used as a silicon source to form what is referred to as TEOS oxide. In one embodiment, the formation of initial dielectric layer 32 occurs, or is performed, at relatively low processing temperatures, such as 550° C. or less, but higher temperatures can also be used. Formation of initial dielectric layer 32 is usefully carried out at processing temperatures between 150° C. and 550° C., more conveniently at processing temperatures between 150° C. and 450° C., and preferably at processing temperatures of approximately 350° C.

Still referring to FIG. 3, initial dielectric layer 32 has width 34 that is similar to diameter 28 of the substrate 20. That is, in one embodiment, initial dielectric layer 32 substantially covers entire upper surface 22 of substrate 20. Initial dielectric layer 32 has a thickness 36 of, for example, usefully between about 10 and 10,000 Angstrom units (\acute{Å}) (1 and 1 k nanometers (nm)), more conveniently about 300 to 3000 \acute{Å} (30 to 300 nm) and in a preferred embodiment, thickness 36 of initial layer 32 is about 1000 \acute{Å} (˜100 nm), but thicker or thinner layers may be used depending upon the combinations of materials included. For example, there is theoretically no upper limit to the thickness of layer 32. However, practical manufacturing considerations suggest that there is little useful purpose served by having thicknesses of layer 32 in excess of about 1 to 10 micrometers (μm). The combination of high resistivity silicon for substrate 20 and initial dielectric layer 32 containing aluminum or silicon nitride or silicon oxide or combinations thereof, prepared by or following a surface damaging pretreatment, may be referred to as a “high resistivity silicon stack.”

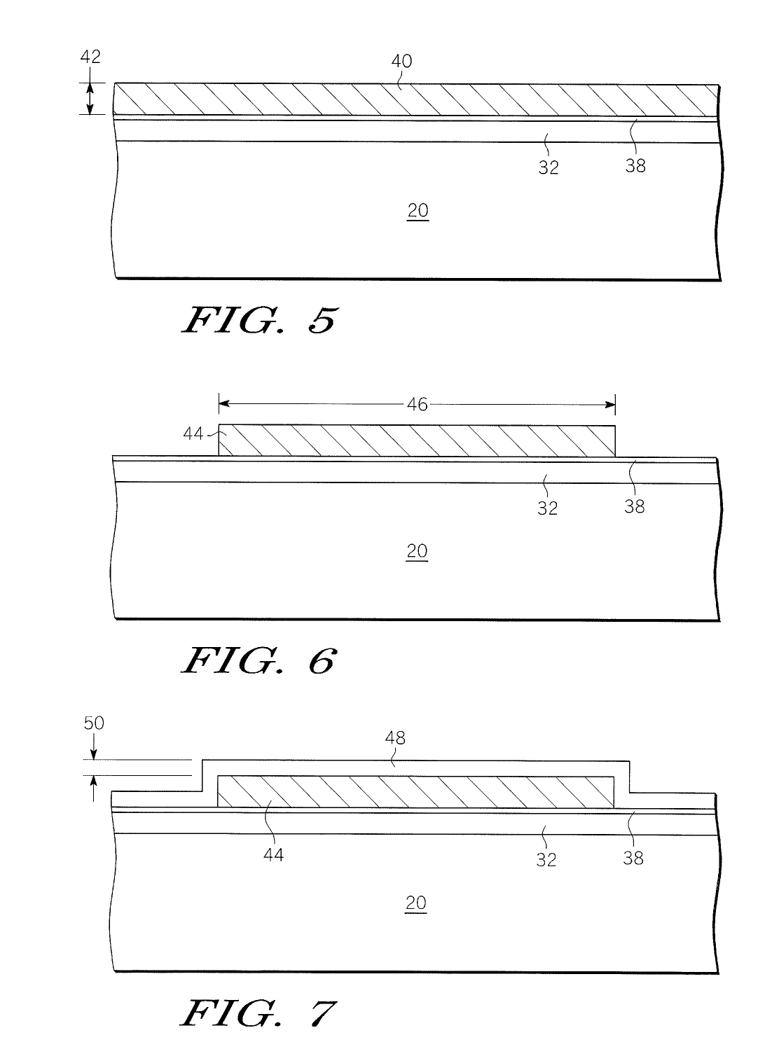

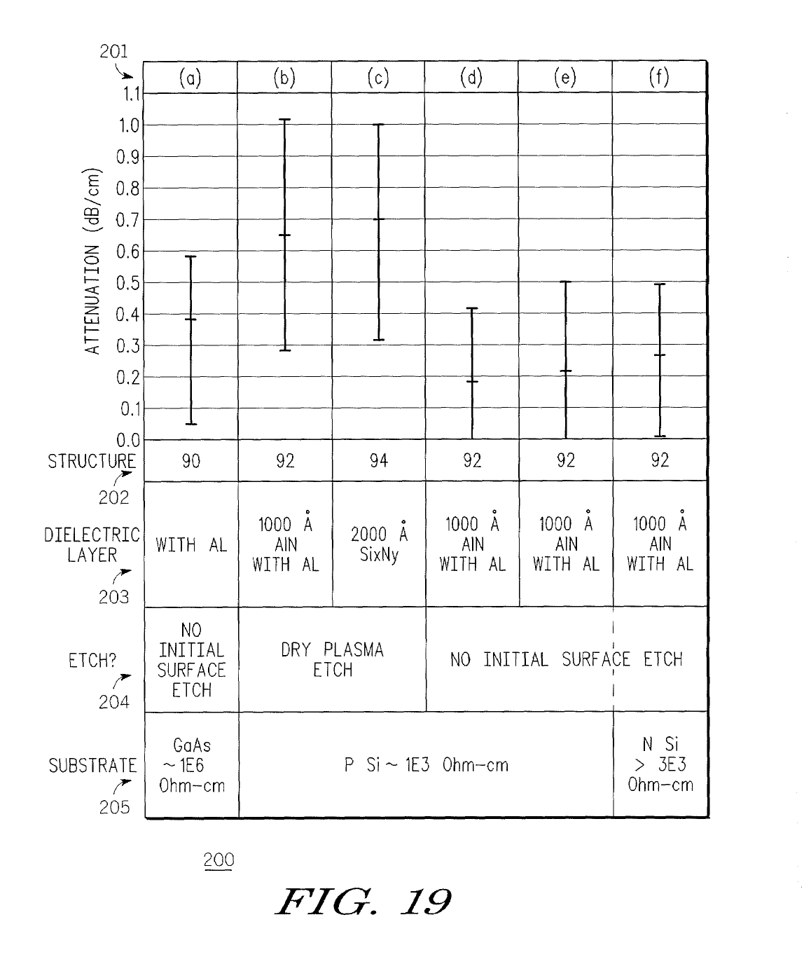

As shown in FIG. 4, adhesion layer 38 is then formed on initial dielectric layer 32. In one embodiment, adhesion layer 38 is made of silicon nitride (SixNy, where x and y indicate the relative proportions of Si and N) and is formed using CVD, such as plasma enhanced PECVD. The silicon nitride used herein for adhesion layer 38 and for other layers is believed to be substantially stoichiometric Si₃N₄, but for convenience of explanation and not intended to be limiting, the abbreviation SixNy will continue to be used in describing the silicon nitride material user herein since it may depart from stoichiometry. Other insulating materials such as silicon oxide may also be used for adhesion layer 38. The formation of adhesion layer 38 may occur, or be performed, at processing temperatures below 550° C., more conveniently in the range of about 150° to 450° C. and preferably about 350° C., but higher temperatures can also be used. For example, and not intended to be limiting, when adhesion layer 38 is used on substrates in which active devices may also be formed, then temperatures of the order of a 850° to 1000° C. may be encountered in conjunction with such active devices, but as indicated above, deposition temperatures below about 550° C. are more useful. Although not specifically shown, adhesion layer 38 has a thickness of, for example, usefully between 50 and 3000 \acute{Å} (5 and 300 nm), more preferably between about 500 and 2000 \acute{Å} (50 and 200 nm) and preferably about 1000 \acute{Å} (100 nm). While adhesion layer 38 is desirable, it is not essential and in further embodiments, adhesion layer 38 may be omitted or combined with initial dielectric layer 32, as indicated by combination dielectric layer 33 in FIG. 5 and following. For convenience of identification in the various figures and associated text, the abbreviation “AL” is used for adhesion layer 38. For example, in FIGS. 18-19, the legend “with AL” indicates that adhesion layer 38 is present with whatever other dielectric layer(s), if any, is indicated.

As shown in FIG. 5, first (or lower) conductive layer 40 is then formed on the adhesion layer 38. Lower conductive layer 40 is made of an electrically conductive material, such as aluminum (Al), copper (Cu), gold (Au), or any practical combination thereof (e.g., AlCu) and is formed using, for example, thermal or electron beam evaporation, physical vapor deposition (PVD), CVD, atomic layer deposition (ALD), or electroplating. Lower conductive layer 40 has a thickness 42 of, for example, between 0.5 and 1.5 μm but thinner and thicker layers can also be used. Lower conductive layer 40 is often referred to in the art as “metal-1” abbreviated as “M1” where several superposed conductive layers are employed in forming IPDs.

Referring to FIG. 6, first (or lower) conductive plate 44 is then formed from M1 layer 40. First conductive plate 44 may be formed by processes well known in the art such as photoresist patterning and plating; physical deposition, patterning and etch; or photoresist patterning, metal evaporation, and lift-off in the case of gold metallization. In one embodiment, first conductive plate 44 has a width 46 of, for example, about 30 μm, more or less, depending on the layout rules being used and, for example when M1 forms one plate of a capacitor, the desired capacitance value.

Referring to FIG. 7, further dielectric layer 48 is then formed over first conductive plate 44, as well as exposed portions of the adhesion layer 38. In one embodiment, further dielectric layer 48 is made of silicon nitride and is formed using substantially the same techniques already discussed. Further dielectric layer 48 has thickness 50 of, for example, between 50 and 500 nm, but thicker and thinner layers may also be used depending on the electrical function to be performed by further dielectric layer 48. Other dielectric materials may also be used for layer 48.

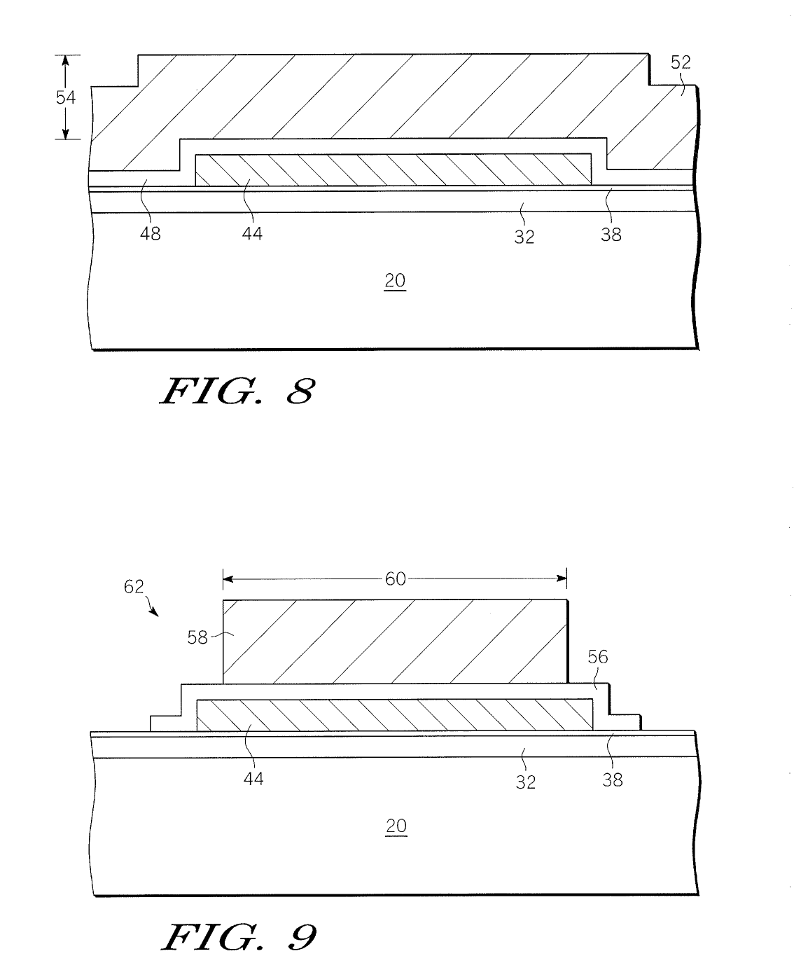

As shown in FIG. 8, second conductive layer 52 is then formed over dielectric layer 48. Second conductive layer 52 is typically referred to in the art as “metal-2” abbreviated as “M2”. M2 layer 52 is made of an electrically conductive material such as for example and not intended to be limiting, aluminum (Al), copper (Cu), gold (Au), or any combination thereof (e.g., AlCu) and is formed using, for example, thermal evaporation, PVD, CVD, ALD, or electroplating. M2 layer 52 has a thickness 54 of, for example, conveniently between 1 and 15 μm.

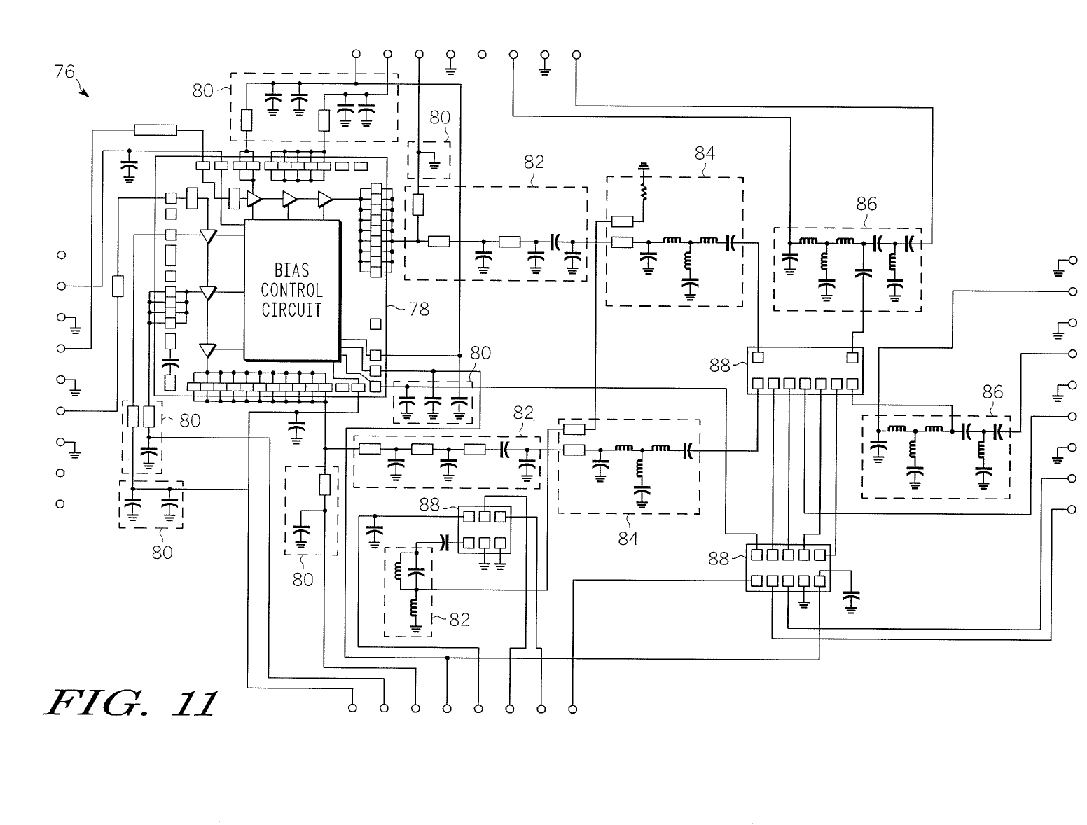

As illustrated in FIG. 9, M2 layer 52, and in some embodiments also dielectric layer 48 are then patterned (and/or etched) to form dielectric body 56 and conductive plate 58 from M2 layer 52, over first conductive plate 44 formed from M1. In the depicted embodiment, dielectric body 56 covers the entire first conductive plate 44 while the second conductive plate 58 conveniently has width 60 that is less than width 46 (FIG. 6) of first conductive plate 44. Width 60 of second conductive plate 58 may be, for example, between 4 and 8 μm but larger or smaller dimensions may also be used depending on the electrical function to be performed by conductive plate 52. The formation of dielectric body 56 and second conductive plate 58 may substantially complete the formation of an integrated, passive electronic component, as for example a capacitor. In the particular exemplary embodiment shown in FIG. 9, the passive electronic component is identified as metal-insulator-metal (MIM) capacitor 62, as is commonly understood in the art. By forming extended regions from M2 layer 52 over dielectric 48, transmission lines and other high frequency structures may also be fabricated in this same general manner.

While not shown in connection with FIGS. 1-9, an additional insulating layer(s) and a third or top metal layer, referred to as “metal-3”, abbreviated as “M3”, may be deposited above the structure of FIG. 9 and appropriately patterned in order to from further conductors, inductors, transmission lines, and additional RF components. The same dielectric and conductor materials may be used for the additional insulating layer(s) and metal layer M3 as were utilized for dielectric layer 48 and M2 layer 52, but other materials may also be used. This is well understood in the art. FIG. 10 is an expanded view of a portion of the substrate (or die 30) illustrated in FIGS. 2-9, but including the additional insulating layer(s) and metal layer M3 noted above. As shown, other passive electronic components can also be formed on the substrate 20, such as thin film resistor 64 and thin film inductor 66. Resistor 64 includes thin resistive film 68 formed on initial dielectric layer 32. In one embodiment, the thin resistive film is made of titanium tungsten nitride (TiWN) with a thickness of, for example, between 100 nm and 300 nm and is formed on initial dielectric layer 32 by CVD. Inductor 66 (e.g., made using layer M3) includes conductive coil 70 that is, for example, made of copper and/or gold with a thickness of between 1 and 15 μm and is conveniently formed using electroplating and patterning.

As will be appreciated by those skilled in the art, resistor 64 and inductor 66 may be at least partially formed during the same processing steps used to form MIM capacitor 62 shown in FIGS. 2-9, such as the formation and etching of first conductive (M1) layer 40 (FIGS. 5 and 6) and second conductive (M2) layer (FIGS. 8 and 9) and the third conductive (M3) layer of FIG. 10. Although not specifically shown, multiple components, formed on substrate 20 (e.g., capacitors 62, resistors 64, and inductors 66, transmission lines, etc. illustrated in FIG. 10) may be coupled such that harmonic filters, couplers, switches, transformers, diplexers and other RF components are formed therefrom (e.g., such as are illustrated in FIG. 11). The formation of the electronic components may substantially complete microelectronic or electronic assembly (or IPD) 72 as shown in FIG. 10 formed on one of dice 30 illustrated in FIG. 1. As also shown in FIG. 10, passivation layer 74 (e.g., CVD SixNy) may be formed over all of the components on substrate 20 to provide protection from environmental effects, such as moisture.

After final processing steps, which may include provision of contacts (e.g., solder balls), conductors (e.g., wire bonds) and planar lead wires interconnecting the electronic components and the contacts, substrate 20 may be sawed into individual microelectronic dice 30, or IPDs, (e.g., such as is shown in FIG. 10), or semiconductor chips, packaged, and installed in various electronic or computing systems. FIG. 11 schematically illustrates an exemplary power amplifier (PA) module 76 in which dice 30 may be utilized. In the depicted embodiment, PA module 76 includes power amplifier (or power integrated circuit) 78, decoupling circuits 80, matching/tuning circuits (including transmission lines and capacitors) 82, couplers (including transmission lines, inductors, resistors and capacitors) 84, harmonic filters (including capacitors and inductors) 86 and control circuits 88, where any or all of elements 76, 80, 82, 84, 86, and 88 may be manufactured in whole or in part utilizing IPDs formed as described herein.

Although not illustrated in detail, the power amplifier may be a “smart” power integrated circuit, as is commonly understood, and may include a power circuit component configured to manage electrical power and at least one additional component configured to control, regulate, monitor, affect, or react to the operation of the power circuit. In practice, the power circuit component may include power transistors, and the at least one additional component may include, without limitation: a sensor (e.g., an environmental condition sensor, an electromagnetic sensor, an electromechanical sensor, an electrical attribute sensor, a transducer, or the like); a power control component; an analog component; a digital logic component; or any combination thereof.

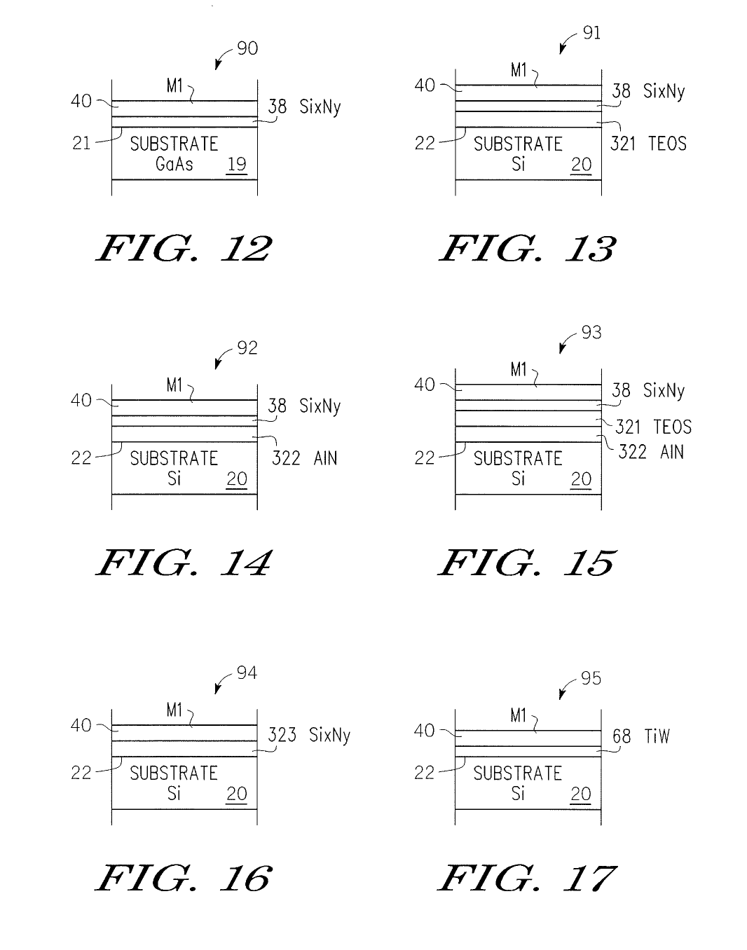

FIGS. 12-17 are cross-sectional side views similar to that of FIG. 5 and following, but showing structures 90-95 corresponding to the manufacturing state illustrated in FIG. 5, for different substrates, different initial dielectric layers and different substrate surface treatments for use as reference structures for comparison test purposes or according to various embodiments of the present invention. FIG. 12 illustrates structure 90 wherein substrate 19 of GaAs has on surface 21 thereof adhesion layer (AL) 38 and M1 40. The use of GaAs substrates is known and this structure is provided as a reference structure for comparison test purposes. However, in order to have an apples-to-apples comparison, AL 38 is also included in this structure since it is present in most of the other structures tested, including structures 91-94 of FIGS. 13-16 according to various embodiments of the present invention.

FIG. 13 illustrates structure 91 in which silicon substrate 20 has TEOS oxide layer 321 placed directly over surface 22 of substrate 20, and with SixNy AL 38 between TEOS layer 321 and M1 layer 40. This structure is also provided for comparison tests purposes when surface 22 is not pretreated.

FIG. 14 illustrates structure 92 in which silicon substrate 20 has aluminum nitride (AlN) layer 322 placed directly over surface 22 of substrate 20, and with SixNy AL 38 between AlN layer 322 and M1 layer 40.

FIG. 15 illustrates structure 93 in which silicon substrate 20 has AlN layer 322 placed directly over surface 22 of substrate 20, with TEOS layer 321 overlying AlN layer 322 and with SixNy AL 38 between TEOS layer 321 and M1 layer 40.

FIG. 16 illustrates structure 94 in which silicon substrate 20 has SixNy layer 323 placed directly over surface 22 of substrate 20. Adhesion layer (AL) 38 is not separately identified in structure 94 since layer 322 is itself of SixNy, but may be considered to be present. In a further embodiment, surface 22 of structure 94 may be pre-treated prior to formation of SixNy layer 323 by, for example, dry plasma etching or other surface damaging means.

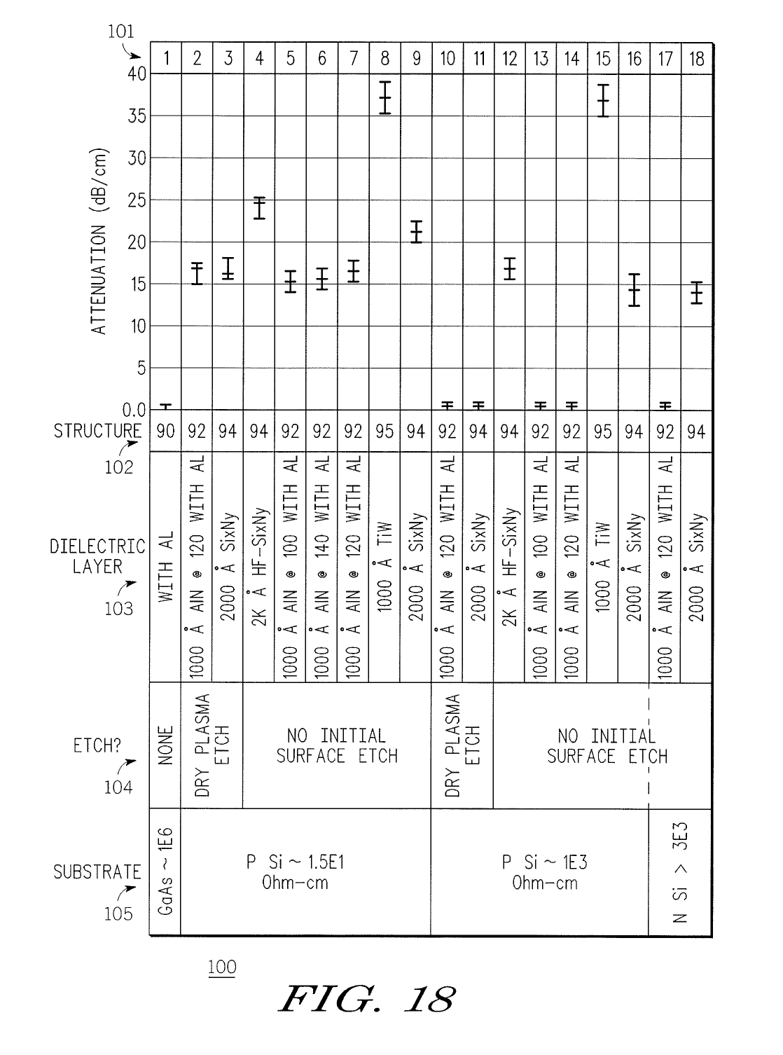

FIG. 17 illustrates structure 95 in which silicon substrate 20 has TiW layer 68 (FIG. 10) placed directly over surface 22 of substrate 20. Adhesion layer (AL) 38 is not included in structure 95, which is also provided for comparison purposes. For convenience of description, the various dielectric layers and combination of layers 321, 322, 323 are referred to collectively as initial dielectric layer(s) 32.

FIG. 18 shows table and chart 100 providing signal attenuation data for different substrates, substrate resistivity, substrate surface treatments and initial dielectric layers, according to various comparison test structures and embodiments of the invention. The attenuation measurements were performed at 5 Giga-Hertz on transmission line structures, specifically a co-planar wave guide (CPW) structure formed, for example, by three parallel M1 conductors overlying various initial dielectric layers, which embodied the various material combinations and treatments noted above and illustrated in FIGS. 12-17. The measurements were performed on multiple samples having the same geometric configuration and processed as described above in connection with FIGS. 1-17. The range of attenuation data observed for each configuration is shown by the “I-beam” like symbols in each column of the upper portion of table 100. The upper bar of the I-beam symbol shows the highest attenuation observed for a particular class of samples, the lower bar of the I-beam symbol shows the lowest attenuation observed for this class of samples and the central bar approximately represents the median value. The median value is that value wherein half of the attenuation values for a given sample are above and half are below the median value.

Continuing to refer to FIG. 18, the numbers from 1 to 18 in row 101 at the top of table and chart 100 are used to identify different samples having different formation procedures and/or different materials for initial dielectric layer 32. The attenuation data in each column were obtained from a number of samples processed substantially in the same way but with different combinations of materials and treatments, for example, according to the structures illustrated in FIG. 12-17. Row 102 of numbers immediately below the attenuation data correlate to FIGS. 12-17 and indicate the type of structure being tested. Second row 103 below the attenuation data identifies the particular combination of materials that made up initial dielectric layer 32, the thickness of various layers and how the substrate and layers were processed The abbreviation “AL” in row 103 indicates that adhesion layer 38 was included in the sample and the suffixes 100, 120, 140 associated with several samples merely indicate for reference purposes the nitrogen flow rate in standard cubic centimeters per minute during the reactive sputtering operation used for deposition of the AlN layers. Third row 104 indicates whether or not any preliminary surface treatment, e.g., dry plasma etching in argon, was provided. Fourth row 105 indicates the semiconductor substrate material (e.g., GaAs or Si) and the conductivity type (P or N) used for substrate 20 and the approximate resistivity thereof.

Considering table and chart 100 of FIG. 18 from left to right, for column 1, the test samples were configured as in structure 90 of FIG. 12 wherein substrate 19 (analogous to substrate 20 of FIG. 5) was high resistivity (˜1E6 Ohm-cm) GaAs, adhesion layer (AL) 38 was formed directly on surface 21 of substrate 19 analogous to surface 22 of substrate 20 and M1 layer 40 was provided over AL 38. It will be noted that very low attenuation was measured, consistent with prior art experience using GaAs substrates.

As noted in row 105, columns 2-9 correspond to P-type Si substrates having comparatively low resistivity of ˜1.5E1 Ohms-cm. As noted in row 104, columns 2-3, correspond to having surface 22 of substrate 20 being RF plasma bombarded or etched in dry argon for about 130 seconds prior to the formation of initial dielectric layer 32. In column 2, structure 92 had initial dielectric layer 322 of AlN plus about 1 k \acute{Å} of AL 38, and in column 3, structure 94 had initial dielectric layer 323 of about 2 k \acute{Å} of SixNy. In both cases, the attenuation was relatively high, indicating that this combination of substrate resistivity, surface treatment and materials did not provide a high enough resistivity surface on the finished silicon substrate. A contributing factor was the relatively low (e.g., 1.5E1 Ohm-cm) resistivity of the silicon substrates for these samples. The samples corresponding to columns 4-9 had the same comparatively low substrate resistivity, were not pre-etched and also gave relatively high attenuation irrespective of the particular combinations of materials making up initial dielectric layer 32. AL 38 was present on all samples.

As shown by row 105, the data in columns 10-16 were obtained using P-type silicon substrates and the data in columns 17-18 were obtained using N-type silicon substrates, all with high resistivity (HR), that is, resistivity equal to or greater than about 1E3 Ohm-cm. As shown by row 104, the data in columns 10-11 was obtained from samples corresponding to structure 92 in column 10 having layer 32 of about 1 k \acute{Å} of AlN plus about 1 k \acute{Å} of AL 38, and structure 94 in column 11 having layer 32 of about 2 k \acute{Å} of SixNy, both after dry plasma etching pre-treatment of surface 22 of substrate 20. Low attenuation values were obtained, indicating that these combinations of materials combined with such surface pre-treatment were successful in providing silicon substrates with substantially depleted surface regions at zero bias that provide low attenuation values and on which low loss IPDs can be formed.

As shown by row 104, columns 12-18 correspond to samples that did not receive a surface pre-treatment etch or equivalent surface damaging treatment. Those samples in columns 13-14 and 17 which used structure 92 incorporating an initial dielectric layer 322 of about 1 k \acute{Å} of AlN plus AL 38 continued to provide low attenuation for both P and N substrates, while structures 94 in columns 16 and 18 having initial dielectric layers 321 of about 2 k \acute{Å} of SixNy (but without the dry plasma etch) did not provide low attenuation. Comparison structure 95 of column 15 (and 8) wherein the initial layer formed on substrate 20 was TiW, provided very high attenuation. This data shows that with high resistivity silicon, a low loss substrate approximately comparable in performance to that of GaAs substrates can be obtained by pre-treating the silicon substrate surface when using SixNy (column 11, structure 94) for the initial dielectric layer or by using an initial dielectric layer comprising AlN with surface pre-treatment (column 10, structure 92) and without surface pre-treatment (columns 13-14, 17, structure 92). This is a significant result since it indicates that when properly prepared, low cost silicon substrates can provide IPDs with the low RF attenuation comparable to that obtained using much more expensive GaAs substrates.

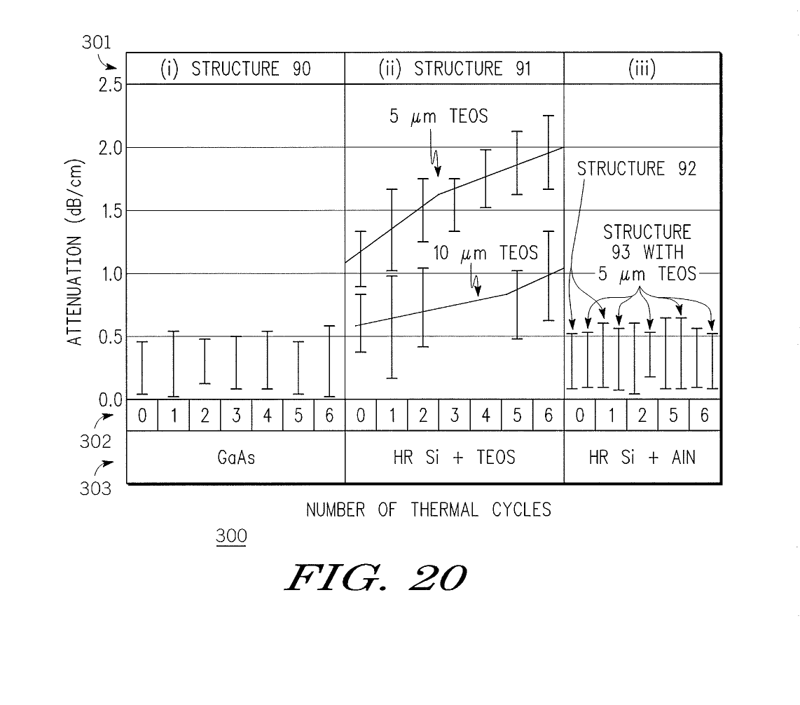

FIG. 19 shows table and chart 200 analogous to table and chart 100 of FIG. 18, but showing further details of signal attenuation for the sub-set of the substrates, substrate surface treatments and initial dielectric layers illustrated in columns 1, 10-11, 13-14, and 17 of FIG. 18. The scale of the abscissa has been enlarged to show the low attenuation data more clearly. Column (a) of FIG. 20 corresponds to column 1 of FIG. 19, wherein a GaAs substrate was used as a reference, column (b) corresponds to column 10, column (c) corresponds to column 11, column (d) corresponds to column 13, column (e) corresponds to column 14 and column (f) corresponds to column 17. The samples presented in columns (b) through (f) utilized high resistivity (≧1E3 Ohm-cm) silicon substrates. Adhesion layer (AL) 38 was present on all samples. GaAs substrates provide an important benchmark for comparison of the improved low loss silicon substrates for IPDs described herein according to several embodiments of the present invention, since the data show that loss characteristics equal or better than those found with GaAs can be obtained using silicon substrates if the silicon substrates are properly configured with certain initial dielectric layers and/or surface treatments. Thus, properly configured silicon substrates can provide a drop-in replacement for GaAs substrates, thereby providing very substantial cost savings because of the large difference in cost of silicon and GaAs wafers and the greater manufacturing convenience of being able to use the same technology already existent for silicon integrated circuit (IC) manufacture, to make IPDs on such silicon substrates.

Adhesion layer 38 was present in all samples. In the case of those samples using SixNy as the initial dielectric layer (see column c), the thickness indicated is the combined thickness of the about 1 k \acute{Å} initial dielectric layer of SixNy plus the about 1 k \acute{Å} thickness of SixNy of AL 38. It will be noted that: (I) structures 92 (columns d-f) comprising AlN in initial dielectric layer 32 on high resistivity (≧1E3 Ohm-cm) silicon substrates with AL 38 and without pre-etching can provide equal or better loss (attenuation) performance as the much higher resistivity (˜1E6 Ohm-cm) and much more expensive GaAs substrates; and, (II) structure 92 (column c) comprising silicon nitride can be substituted for AlN if a pre-deposition substrate surface treatment is provided, thereby resulting in loss performance (e.g., median attenuation ˜0.7 dB/cm) close to that of high resistivity GaAs (median attenuation of ˜0.38 dB/cm). While the preferred pre-deposition surface treatment when using SixNy as the initial dielectric layer has been referred to herein as an “etch”, this is not intended to be limiting. It is believed that the beneficial effect of the dry argon RF plasma to which the substrate surface is exposed during the so-called “etch” or “pre-treatment” is related to significant bombardment surface damage occurring during such plasma exposure and that this surface damage may be more important in obtaining a substrate surface underneath the initial dielectric layer that is depleted of free carriers at zero bias (and therefore less lossy) than is the removal of material normally associated with an “etch” process. Thus, removal of significant material from the substrate surface is not likely to be essential to the embodiment wherein plasma exposure is used to provide lower loss substrates in connection with a SixNy initial dielectric layer. Other surface damaging techniques and other initial dielectric layer materials may also be useful. It is noted that the AlN used with very favorable results for the initial dielectric layer is preferably reactively sputtered, a process also likely to bombard the silicon substrate surface with energetic and damage causing particles. Thus, deposition of the AlN nitride may also be accompanied by surface damage as a consequence of the sputter deposition, even though no pre-treatment is expressly provided. Hence, it is likely that other surface damaging treatments can provide similar benefits. Also, while SixNy is convenient for use in connection with pre-deposition plasma exposure of the surface in order to obtain lower loss substrates, other materials can also be used, provided that in combination with surface damage produced by plasma exposure or other surface damaging pre-treatment, the resulting dielectric coated surface has a lower near surface carrier concentration at zero bias and thereby lower attenuation at high frequencies for use in manufacturing modern day IPDs.

Capacitance-voltage (CV) plots were obtained on structure 92 of FIG. 14 embodying AlN (plus AL 38 of SixNy) on 15 Ohm-cm silicon. These CV plots show that the silicon surface (e.g., surface 22) is substantially depleted of free carriers at zero bias. The CV plot capacitance increases as a consequence of applied bias voltage because the applied voltage can cause significant accumulation of free carriers at the surface. Conversely, the capacitance is lowest when the semiconductor surface is depleted of free carriers. Those samples using AlN for initial dielectric layer 32 had minimum capacitance for several volts on either side of zero bias and did not show increased capacitance until larger voltage was applied. This indicates that the surface regions of these silicon substrates are essentially depleted of free carriers at zero bias and for several volts on either side.

Surface depletion can come about as a result of fixed charges trapped in the dielectric or at the dielectric-semiconductor interface or within the near surface region of the semiconductor. Surface traps created by sputtering a dielectric (e.g., AlN) film onto the surface or by exposing the surface to energetic particles, as for example and not intended to be limiting, by an RF plasma or by other surface damaging means can provide such charge trapping sites and give rise to the observed shifted CV curves and low RF attenuation. In addition to creating charge traps in or at the semiconductor surface, a dielectric film deposited on the high resistivity silicon substrate, can incorporate sufficient fixed charge to deplete the silicon surface at and near zero bias. Thus, trapped charge in the dielectric or at the dielectric-semiconductor interface or in a near surface damage region of the silicon substrate can deplete the surface of the silicon of free carriers at zero bias, thereby reducing the attenuation of RF signals present in transmission lines or other passive components formed on or above initial dielectric layer 32. This is believed to account, in whole or in part, for the improved performance of the samples illustrated in columns (b) through (f) of FIG. 19 on silicon substrates. While the particular materials and treatments described herein are successful in providing the desired fixed charge sufficient to deplete the surface of the high resistivity silicon substrates, the present invention is not limited thereto and any material, surface treatment and layer formation process or combination thereof that accomplishes this result can also be used.

Another element of concern with respect to obtaining less expensive low loss substrates for IPDs is the thermal stability of such substrates. For example, it is known that when using silicon oxide as the initial dielectric layer (e.g., structure 91 of FIG. 13), that the substrate related attenuation (loss) can be reduced compared to substrates without such an oxide layer, and that the thicker the oxide layer the lower the loss. FIG. 20 shows table and chart 300 plotting signal attenuation (loss) measured at 5 Giga-Hertz in the same way as for the data of FIGS. 18-19, as a function of the number of thermal cycles to which the test transmission line structure has been subjected, for various types of substrates and initial dielectric layers. Each sample was measured, then thermally cycled and then measured again and the process repeated for the number of thermal cycles shown in row 302 of FIG. 20. As before, the “I-beam” shaped symbols show the range of data obtained from each test sample. Row 302 identifies the number of the thermal cycles associated with each data set. Thus, the data presented from left to right in each column (i) though (iii) (see row 301) is the behavior of the same sample before (0) and after each [(1) . . . (6)] thermal cycle. Each thermal cycle was at 325 degrees Celsius for five minutes per cycle. Adhesion layer 38 was included in all samples. Row 301 identifies columns (i) through (iii). Column (i) shows the attenuation behavior of samples with GaAs substrates. Essentially, for a GaAs substrate with CPW test structures similar to those used for the data of FIGS. 18-19, there was no significant change as a result of the thermal cycling. Column (ii) shows the attenuation behavior of the same type of test structures formed on high resistivity (≧1E3 Ohm-cm) silicon with a TEOS oxide as the initial dielectric layer (e.g., structure 91). Two thicknesses of TEOS were used: 5 micro-meters (μm) and 10 micro-meters (μm), as noted on FIG. 20. It will be observed that the use of ˜10 μm of TEOS for initial dielectric layer 321 of structure 91 provided reasonably low attenuation (e.g., median value ˜0.6 dB/cm compared to ˜0.25 dB/cm for GaAs), but that the loss for the TEOS initial dielectric samples increased with each thermal cycle, rising to about 1.0 dB/cm after thermal cycle number 6 for the 10 μm thick layers. The thermal drift for the 5 μm thick TEOS layers was worse. This thermal drift is not desirable. Column (iii) shows the result of thermal cycling of devices having about 1 k \acute{Å} of AlN initial dielectric layer for structure 92 with no TEOS layer and for structure 93 with about 1 k \acute{Å} of AlN plus about a 5 μm TEOS layer. It will be noted that the test devices having an initial dielectric layer comprising AlN, showed no significant change in attenuation after such thermal cycling, irrespective of whether or not they included a TEOS layer. Thus, use of an initial dielectric layer comprising AlN makes it possible not only to provide much lower cost substrates for IPDs but also substrates that are as thermally stable as much more expensive GaAs substrates.

One advantage of the structure and method of forming IPDs described above is that the effective resistivity of the silicon substrate is increased because of the use of an initial dielectric layer of AlN, or use of an initial dielectric layer of SixNy combined with a substrate surface pre-treatment that, it is believed, produces surface damage. As a result, the substrate losses experienced by IPDs embodying these improved silicon substrates are minimized, and the overall RF performance of the IPD's is improved while benefiting from the very substantial cost reduction associated with use of silicon substrates as opposed to GaAs, quartz, sapphire, and other prior art substrates. Another advantage is that because of the relatively low cost of silicon, especially when compared to gallium arsenide, quartz and sapphire, the overall manufacturing costs of IPDs is minimized without sacrificing performance. A further advantage is that because silicon is already commonly used in semiconductor manufacturing, the same processes and tools may be used to form such IPDs without substantial modification. As a result, the manufacturing costs are even further reduced, especially when compared to glass and quartz substrates that require special handling. Even compared to silicon substrates using thick TEOS layers as the initial dielectric layer, the invented structure and process provides not only superior loss performance but saves substantial manufacturing time and cost since the very thick (e.g., ˜10 μm) TEOS layers are replaced by, for example, comparatively thin (˜1 k \acute{Å}) AlN or (˜1-2 k \acute{Å}) SixNy layers that are one and a half to two orders of magnitude thinner than the TEOS initial dielectric layers. The economic advantage of using less dielectric are improved cycle time, more capacity with existing tools (no need to purchase addition tools to accommodate very long 10 μm thick processing times) and lower chemical expense.

Silicon substrates prepared according to the structure and methods described herein can have attenuation loss properties substantially equal to or better than is observed using much more expensive GaAs substrates. Further, such improved silicon substrates are thermally stable, that is, the reduced attenuation loss does not deteriorate as a consequence of thermal cycling. Further, the much thinner crucial layers that contribute to the improved attenuation performance of the improved silicon substrates are more economical to manufacture because of the reduced cycle time and improved tool and chemical usage. Further, the improved silicon substrates of lower cost and improved performance can be utilized according to the process steps described herein to fashion complex IPDs, for example and not intended to be limiting, IPDs 78, 80, 82, 84, 86, 88 that contribute in whole or part to power amplifier module 76 of FIG. 11. IPDs can also be fashioned according to the teachings herein to provide improved, inductors, capacitors, resistors, transmission lines, antennas, matching networks, decoupling circuits, filter circuits, diplexers, harmonic filters, and many other types of passive components and circuits for a wide variety of applications, but especially those operating at high frequencies where attenuation loss is of great concern. These are significant advantages of the present invention.

According to a first embodiment, there is provided a method of forming an integrated passive device (IPD) comprising, forming an insulating initial dielectric layer comprising aluminum nitride over a silicon substrate, and forming at least one passive electronic component over the insulating initial dielectric layer. According to a further embodiment, the insulating initial dielectric layer is an aluminum nitride layer and the at least one passive electronic component comprises at least one of a capacitor, a resistor, an inductor and a transmission line. According to a still further embodiment, the insulating initial dielectric layer comprises an aluminum nitride layer and another dielectric layer. According to a yet further embodiment, the another dielectric layer comprises silicon nitride. According to a still yet further embodiment, the another dielectric layer comprises silicon oxide. According to a yet still further embodiment, the insulating initial dielectric layer is formed at a temperature that is between approximately 150° C. and 550° C. According to another embodiment, the insulating initial dielectric layer is formed by reactive sputtering. According to a still another embodiment, the thickness of the insulating dielectric layer is between approximately 10 and 10,000 Angstrom Units. According to a yet another embodiment, the thickness of the insulating initial dielectric layer is between approximately 300 and 3000 Angstrom Units. According to a yet another embodiment, the thickness of the insulating initial dielectric layer is about 1000 Angstrom Units.

According to a second embodiment, there is provided a method for forming an integrated passive device (IPD) comprising, providing a silicon substrate with a resistivity equal to or greater than about 1000 ohm-cm and having an outer surface, exposing the outer surface of the substrate to a surface damage causing circumstance, forming an initial dielectric layer comprising aluminum nitride, silicon nitride, TEOS or a combination thereof over the outer surface, and forming a plurality of passive electronic components over the initial dielectric layer. According to a further embodiment, the surface damage causing circumstance is exposure to a plasma formed using a substantially inert gas. According to a still further embodiment, the substantially inert gas is argon. According to a yet further embodiment, the surface damage causing circumstance is deposition of a sputtered aluminum nitride layer. According to a still yet further embodiment, the plurality of passive electronic components comprises at least one of a capacitor, a resistor, a transmission line and an inductor and said formation of the plurality of passive electronic components comprises, forming a first conductive layer over the initial dielectric layer, and forming a second conductive layer over the first conductive layer.

According to a third embodiment, there is provided a microelectronic assembly comprising, a silicon substrate with a resistivity of at least 1000 ohm-cm, an initial dielectric layer comprising aluminum nitride, and a plurality of passive electronic components formed over the initial dielectric layer. According to a further embodiment, the initial dielectric layer further comprises silicon nitride. According to a still further embodiment, the plurality of passive electronic components comprises at least one of a capacitor, a resistor, a transmission line and an inductor. According to a yet further embodiment, the plurality of passive electronic components jointly form a harmonic filter, coupler, or a transformer. According to a still yet further embodiment, the microelectronic assembly further comprises an integrated circuit coupled to the plurality of passive electronic components.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method of forming an integrated passive device (IPD) comprising:
forming an insulating initial dielectric layer comprising aluminum nitride over a silicon substrate; and
forming at least one passive electronic component over the insulating initial dielectric layer.

2. The method of claim 1, wherein the insulating initial dielectric layer is an aluminum nitride layer and the at least one passive electronic component comprises at least one of a capacitor, a resistor, an inductor and a transmission line.

3. The method of claim 1, wherein the insulating initial dielectric layer comprises an aluminum nitride layer and another dielectric layer.

4. The method of claim 3, wherein the another dielectric layer comprises silicon nitride.

5. The method of claim 3, wherein the another dielectric layer comprises silicon oxide.

6. The method of claim 1, wherein the insulating initial dielectric layer is formed at a temperature that is between approximately 150° C. and 550° C.

7. The method of claim 1, wherein the insulating initial dielectric layer is formed by reactive sputtering.

8. The method of claim 1, wherein the thickness of the insulating initial dielectric layer is between approximately 10 and 10,000 Angstrom Units.

9. The method of claim 8, wherein the thickness of the insulating initial dielectric layer is between approximately 300 and 3,000 Angstrom Units.

10. The method of claim 9, wherein the thickness of the insulating initial dielectric layer is about 1000 Angstrom Units.

11. A method for forming an integrated passive device (IPD) comprising:
providing a silicon substrate with a resistivity equal to or greater than about 1000 ohm-cm and having an outer surface;
exposing the outer surface of the substrate to a surface damage causing circumstance;
forming an initial dielectric layer comprising aluminum nitride, silicon nitride, TEOS or combinations thereof, substantially over the outer surface; and
forming a plurality of passive electronic components over the initial dielectric layer.

12. The method of claim 11, wherein the surface damage causing circumstance is exposure to a plasma formed using a substantially inert gas.

13. The method of claim 11, wherein the substantially inert gas is argon.

14. The method of claim 11, wherein the surface damage causing circumstance is deposition of a sputtered aluminum nitride layer.

15. The method of claim 11, wherein the plurality of passive electronic components comprises at least one of a capacitor, a resistor, a transmission line and an inductor, and said formation of the plurality of passive electronic components comprises:
forming a first conductive layer over the initial dielectric layer; and
forming a second conductive layer over the first conductive layer.

16. A microelectronic assembly comprising:
a silicon substrate with a resistivity of at least 1000 ohm-cm;
an initial dielectric layer comprising aluminum nitride; and
a plurality of passive electronic components formed over the initial dielectric layer.

17. The microelectronic assembly of claim 16, wherein the initial dielectric layer further comprises silicon nitride or TEOS.

18. The microelectronic assembly of claim 16, wherein the plurality of passive electronic components comprises at least one of a capacitor, a resistor, a transmission line and an inductor.

19. The microelectronic assembly of claim 16, wherein the plurality of passive electronic components jointly form a harmonic filter, a coupler or a transformer.

20. The microelectronic assembly of claim 16, further comprising an integrated circuit coupled to the plurality of passive electronic components.
